(19) United States
(12) Patent Application Publication
(10) Pub. No.: US 2025/0227866 A1
(43) Pub. Date: Jul. 10, 2025

(54) EXPLOSION-RESISTANT DEVICE WITH GRAPHICAL INTERFACE ASSEMBLY AND METHODS THEREOF

(71) Applicant: ABB Schweiz AG, Baden (CH)

(72) Inventors: Michael J. May, Bartlesville, OK (US); Donald R. Adams, Bartlesville, OK (US); Brian C. Smith, Bartlesville, OK (US); Brian J. Robertson, Bartlesville, OK (US)

(21) Appl. No.: 19/095,295

(22) Filed: Mar. 31, 2025

Related U.S. Application Data
(63) Continuation of application No. PCT/US2022/079678, filed on Nov. 11, 2022.

(51) Int. Cl. H05K 5/02; G06F 3/044; G06F 3/14; H05K 5/00

(52) U.S. Cl. CPC H05K 5/0217; G06F 3/0443; G06F 3/14; H05K 5/0018

(57) ABSTRACT

An explosion-resistant device is provided. The explosion-resistant device includes an enclosure defining a control compartment and a display compartment. The display compartment is isolated from the control compartment. The explosion-resistant device also includes a graphical interface assembly received in the display compartment. The graphical interface assembly is configured to present visual information and receive input from a user. The graphical interface assembly includes a display sensor assembly including a face plate, a backing plate, and a sensor layer positioned between the face plate and the backing plate and configured to detect touch of the user.

### CROSS-REFERENCE TO RELATED APPLICATIONS

This application is a continuation of International Patent Application No. PCT/US2022/079678, filed Nov. 11, 2022 and titled “EXPLOSION-RESISTANT DEVICE WITH GRAPHICAL INTERFACE ASSEMBLY AND METHODS THEREOF”, which is hereby incorporated by reference in its entirety.

### BACKGROUND

The field of the disclosure relates generally to systems and methods of explosion management, and more particularly, to an explosion resistant device.

Field instruments, such as sensors, analyzers, and interfaces are used in various industrial devices, systems, and/or methods. In environments in which explosive substances, such as alcohols and/or petroleum products, are present or may potentially be present, (e.g., a harsh or hazardous environment) hazards of igniting the explosive substance via electronic equipment within the field instruments may exist. For example, some field instruments may be involved with explosive substances, such as sensors for a production process, where the explosive substances are within the precursor, intermediate product, incidental product, and/or final product. Additionally, the field environment for such instruments may contain explosive substances, for example, gases, which could be ignited by the electronic equipment of the instruments and/or by an explosion originating from within the instruments.

Known field instruments are disadvantaged in some aspects, and improvements are desired.

### BRIEF DESCRIPTION

In one aspect, an explosion-resistant device is provided. The explosion-resistant device includes an enclosure defining a control compartment and a display compartment. The display compartment is isolated from the control compartment. The explosion-resistant device also includes a graphical interface assembly received in the display compartment. The graphical interface assembly is configured to present visual information and receive input from a user. The graphical interface assembly includes a display sensor assembly including a face plate, a backing plate, and a sensor layer positioned between the face plate and the backing plate and configured to detect touch of the user.

In another aspect, a method of assembling a device for a harsh and hazardous environment is provided. The method includes providing a graphical interface assembly configured to present visual information and receive input from a user. The graphical interface assembly includes a face plate, a backing plate, and a sensor layer positioned between the face plate and the backing plate and configured to detect touch of the user. The method further includes providing a bezel plate defining an opening that has a perimeter complementary to a perimeter of the graphical interface assembly, and receiving the graphical interface assembly in the opening of the bezel plate. The device is explosion resistant.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings.

FIG. 1 is a perspective view of an example explosion-resistant device.

FIG. 2A is a sectional view of the device shown in FIG. 1 taken along line 2A-2A in FIG. 1 showing components of an example display assembly.

FIG. 2B is an exploded view of the display assembly shown in FIG. 2A.

FIG. 2C is a sectional view of the device shown in FIG. 1 taken along line 2A-2A in FIG. 1 showing components of another example display assembly.

FIG. 3A is a front view of an example graphical interface assembly of the display assembly shown in FIG. 2B.

FIG. 3B is a side view of the graphical interface assembly shown in FIG. 3A.

FIG. 3C is a rear perspective view of the graphical interface assembly shown in FIG. 3A.

FIG. 4A is a perspective view of an example bezel plate of the explosion-resistant device of FIG. 1.

FIG. 4B is a rear view of the bezel plate shown in FIG. 4A.

FIG. 4C is an enlarged detail view of the bezel plate of the display assembly shown in FIG. 2B.

FIG. 5A is a rear perspective view of an example captivation plate of the display assembly shown in FIG. 2B.

FIG. 5B is a front view of the captivation plate shown in FIG. 5A.

FIG. 5C is a top view of the captivation plate shown in FIG. 5A.

FIG. 5D is a side view of the captivation plate shown in FIG. 5A.

FIG. 6A is a perspective view of an example display interface printed circuit board assembly (PCBA) of the display assembly shown in FIG. 2B.

FIG. 6B is a perspective view of an example display pass-through assembly of the display assembly shown in FIG. 2B.

FIG. 6C is a perspective view of an example retainer of the display pass-through assembly shown in FIG. 6B.

FIG. 7A is a rear perspective view of an example feed-through plate of the display assembly shown in FIG. 2B.

FIG. 7B is a front perspective view of the feed-through plate shown in FIG. 7A.

FIG. 8 is a flow chart illustrating an example method of assembling a device for a harsh and hazardous environment.

### DETAILED DESCRIPTION

The present disclosure includes systems and methods of explosion management by using an explosion-resistant device having a display assembly including a graphical interface assembly configured to present visual information and receive input from a user. Method aspects will be in part apparent and in part explicitly discussed in the following description.

Electronic instrumentation (e.g., electronic measurement instruments and displays) may assist in high quality, safe, and/or efficient process management. In environments in which explosive and/or flammable substances may be present (e.g., in a harsh and/or hazardous environment), electronic instrumentation may pose an explosion risk. In particular, when using electronic instrumentation to conduct field analyses of process substances with flammability and/or explosion risks, the electronic instrumentation may pose a risk of ignition. For example, flammable and/or explosive gases to be analyzed by electronic instrumentation may be ignited if the flammable and/or explosive gases come into contact with components of the electronic instrumentation. Within the present disclosure, the resistance to explosion and/or flammability risks, including from electronic instrumentation, is described as explosion resistance.

An explosion-resistant device that operates within harsh or hazardous environments presents a risk of explosion via ignition of a surrounding gas or vapor dusts, fibers, or flyings. Such harsh or hazardous environments may arise, for example only, in petroleum refineries, petrochemical plants, grain silos, wastewater, and/or treatment facilities among other industrial facilities, where volatile conditions are produced in the ambient environment and present a heightened risk of fire or explosion. An occasional or continuous presence of airborne ignitable gas, ignitable vapors or dust, or otherwise flammable substances presents substantial concerns regarding safe and reliable operation of such facilities overall, including, but not limited to, safe operation of the explosion-resistant device such as containing sparks within the explosion-resistant device to prevent possible fire or explosion. As such, a number of standards have been promulgated relating to electrical products used in explosive environments to improve safety in hazardous locations in view of an assessed probability of explosion or fire risk.

For example, Underwriter's Laboratories (“UL”) standard UL 1203 sets forth Explosion-Proof and Dust-Ignition-Proof Electrical Equipment criteria for hazardous locations. Electrical equipment manufacturers may receive UL certification of compliance with the applicable rating standards for hazardous locations, and UL certification is an important aspect of a manufacturer's ability to successfully bring products to market in North America or any other market accepting UL standard 1203.

The National Electric Code (NEC) generally classifies hazardous locations by class and division. Class I locations are those in which flammable vapors and gases may be present. Class II locations are those in which combustible dust may be found. Class III locations are those which are hazardous because of the presence of easily ignitable fibers or flyings. Considering Class I, Division 1 covers locations where flammable gases or vapors may exist under normal operating conditions or under frequent repair or maintenance operations, or where breakdown or faulty operation of process equipment might also cause simultaneous failure of electrical equipment. Division 1 presents a greater risk of explosion than, for example, Division 2 where flammable gases or vapors are normally handled either in a closed system, confined within suitable enclosures, or are normally prevented by positive mechanical ventilation.

The International Electrotechnical Commission (IEC) likewise categorizes hazardous locations into Class I, Zone 0, 1, or 2 representing locations in which flammable gases or vapors are or may be airborne in an amount sufficient to produce explosive or ignitable mixtures. As defined by the IEC, a Class I, Zone 0 location is a location in which ignitable concentrations of flammable gases or vapors are present continuously or for long periods of time. A Class I, Zone 1 location is a location in which ignitable concentrations of flammable gases or vapors are likely to exist because of repair or maintenance operations or because of leakage or possible release of ignitable concentrations of flammable gases or vapors, or is a location that is adjacent to a Class I, Zone 0 location from which ignitable concentrations of vapors could be communicated.

Electronic instrumentation may exist in harsh or hazardous external environments which may include flammable and/or explosive substances, such as in petrochemical production facilities. Thus, in addition to the hazards of electronic instrumentation generating internal ignition, the electronic instrumentation may pose further risk to external environments.

Further, some external environments may pose additional risk to electronic instrumentation. For example, ignition sources external to the electronic instrumentation may present a risk to the electronic instrumentation. In such environments, it is desirable to prevent an ignition of flammable and/or explosive substances within the external environment (and outside of the electronic instrumentation) from entering the electronic instrumentation.

Some conventional explosion-resistant devices include measurement instruments, (e.g., sensors) to analyze a sample (e.g., a gas), and a display, to display data associated with the analysis. Conventional explosion-proof devices include a single, thick layer of material (e.g., glass) in front of the display that provides explosion resistance while also allowing a user to view data displayed on the display. While the single, thick layer of material between the display and the user in conventional explosion-resistant devices provides explosion resistance, the single, thick layer of material limits user interaction with the display of the explosion-resistant device.

For example, some conventional explosion-resistant devices include a touch-screen display that displays information to a user and accepts input from a user via touch sensors located adjacent to the display. In conventional explosion-resistant devices, the sensitivity (e.g., accuracy and precision) of touch sensors that enable user input on a touch-screen display is degraded because the thickness of a material (e.g., single, thick layer of material) located between the user and the touch sensors is relatively large in order to provide explosion resistance. A single, thick layer of material between the touch sensors and the user makes it more difficult for a user to input operations into the touch-screen display than if the material were thinner.

Further, conventional explosion-resistant devices include wires and/or cables to connect a display assembly to other electronic assemblies (e.g., analysis equipment and/or control equipment). The inclusion of wires and/or cables requires that additional space be included within the explosion-resistant device to accommodate the installation (e.g., bending) of the wires and/or cables. Additional space within an explosion-resistant device may increase the risk of an explosion within the explosion-resistant device by providing additional space within the explosion-resistant device for explosive and/or flammable gases, exacerbating fire risks.

Additionally, the inclusion of wires and/or cables to connect adjacent electronic assemblies may negatively affect the electrical connections from wire and/or cable twisting. With wires and/or cables electrically connected to other electronic components, rotation of mechanical structures twist the wires and/or cables, degrading or compromising electrical connections.

In contrast, the systems and methods described herein include an explosion-resistant device that includes a display assembly that increases sensitivity of user interaction with a touch-screen display. The explosion-resistant device described herein also enhances safety by reducing space within the explosion-resistant device in which explosive and/or flammable gases may collect. The explosion-resistant device described herein further enables enhanced electrical connection between electronic assemblies via replacing some wires and/or cables with PCBAs.

In the systems and methods described herein, the explosion-resistant device includes a graphical interface assembly including a face plate and a backing plate located in front of a display, with a sensor layer (e.g., a touch sensor layer) positioned between the face plate and the backing plate, thereby reducing the distance between the sensor layer and the user. This configuration increases the sensitivity of the sensor layer, thereby increasing the precision and accuracy of user inputs into the graphical interface assembly.

Additionally, in the systems and methods described herein, the connection between the display assembly and other electronic assemblies (e.g., analysis equipment and/or control equipment) is provided via PCBA, instead of wires and/or cables. Replacement of wires and/or cables with PCBAs reduces space within the explosion resistant device in which explosive and/or flammable gases may collect and provides a compact design of the explosion-resistant device. For example, the elimination of wires and/or cables to connect the display assembly with other electronic assemblies eliminates the need to include extra space within the explosion-resistant device to accommodate the installation and bending of wires and/or cables. The connection between the display assembly and other electronic assemblies via PCBA also enables enhanced electrical connection because connecting the assemblies using connectors included on PCBAs, instead of wires and/or cables, eliminates or reduces twisting of the wires and/or cables and degradation of the connections caused by twisting.

Further, in the systems and methods described herein, the explosion-resistant device includes a compact design in which adjacent components (e.g., a bezel plate and the graphical interface assembly) are formed complementary or nearly complementary to one another in order to reduce space within the explosion-resistant device.

In addition, in the systems and methods described herein, the explosion-resistant device includes flame paths defined between various components (e.g., between the bezel plate and a feed-through plate and between the feed-through plate and a display pass-through assembly) that are paths on which exploding gases may be cooled and fire may be extinguished. In the event of an explosion within the explosion-resistant device, the flame paths help to contain the explosion within the explosion-resistant device, thereby enhancing the safety of users. The systems and methods described herein include flame paths such that the explosion-resistant devices described herein meet the standards stipulated in UL 1203, IEC 60079-0, IEC 60079-1, and CSA C22.2 No. 30.

As space within a device increases, the required length of a flame path within the device to meet a standard may also increase. The systems and methods described herein provide an explosion-resistant device that reduces space therein. Therefore, the explosion-resistant device described herein also requires shorter flame paths than conventional explosion-resistant devices in order to meet the standards stipulated in UL 1203, IEC 60079-0, IEC 60079-1, and CSA C22.2 No. 30. Shorter flame paths allow smaller sizes of parts and/or assemblies that contain the flame paths to be used to construct the explosion-resistant device, thereby reducing the amount of material required to construct the explosion-resistant device. Shorter flame paths also, in turn, reduce cost of producing explosion-resistant devices via the smaller parts and assemblies (e.g., by reducing material cost) required for the shorter flame paths.

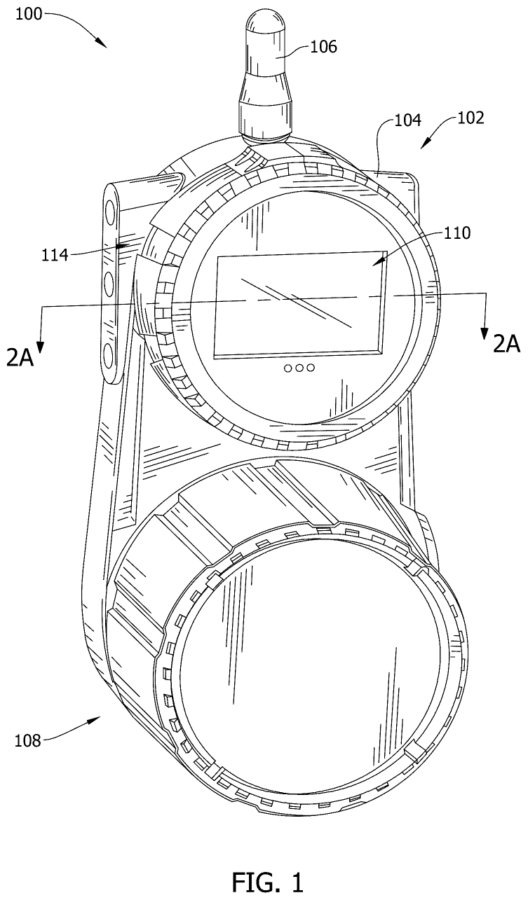

FIG. 1 is a perspective view of an explosion-resistant device 100. In the example embodiment, explosion-resistant device 100 includes an explosion-resistant enclosure 102. Explosion-resistant enclosure 102 includes a housing 104 that defines an interior for receiving equipment therein, and an antenna 106 for communicating wireless signals, for example, Wi-Fi signals, although in some embodiments, explosion-resistant device 100 may be partly or wholly wired for communication.

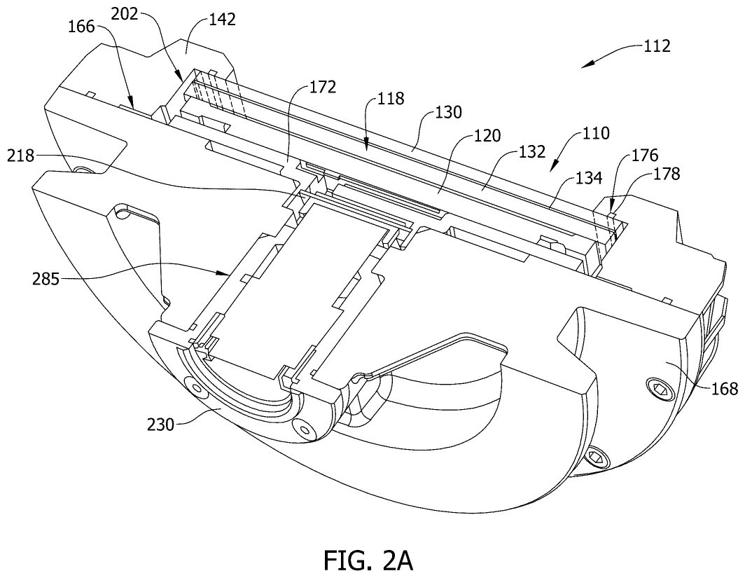

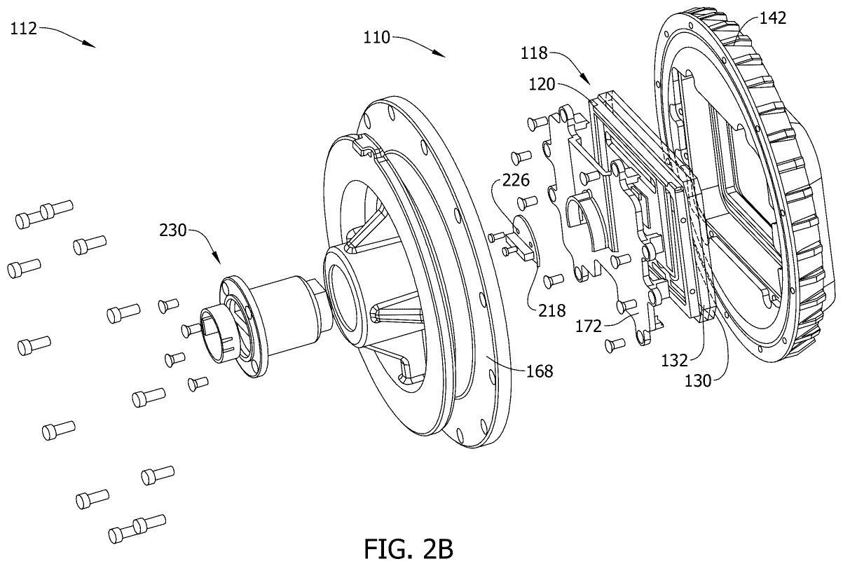

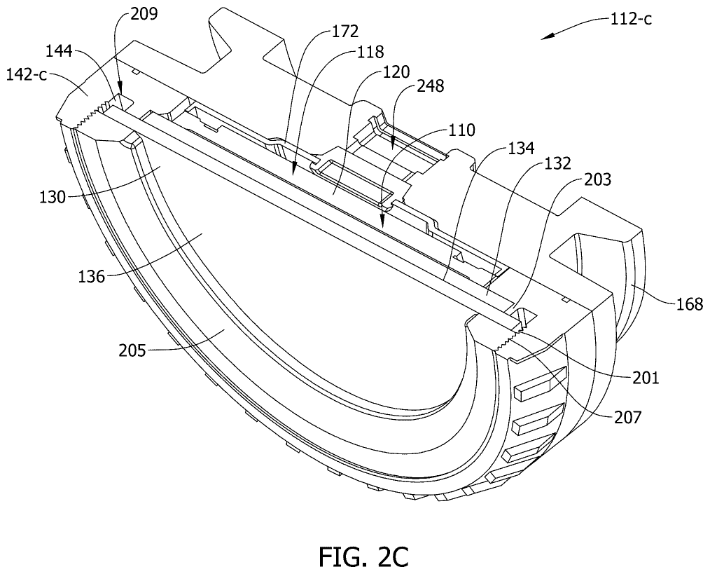

In the example embodiment, housing 104 includes an analysis compartment 108 for receiving analysis equipment. Housing 104 also includes a display compartment 110 for receiving a display assembly 112 (shown in FIG. 2B described later). Housing 104 further includes a control compartment 114 for receiving control equipment. Display compartment 110 is separate from analysis compartment 108, such that display compartment 110 and analysis compartment are positioned within different portions of explosion-resistant device 100. Display compartment 110 is positioned near and isolated from control compartment 114. In some embodiments, explosion-resistant enclosure 102 may define control compartment 114, analysis compartment 108 and/or display compartment 110.

Analysis equipment may include gas chromatography analysis modules for conducting gas chromatography analysis, and may include one or more solenoid valves, sensors, heaters and/or other equipment operated under guidance of control equipment. Control equipment may include control circuitry for governing control and/or communication of gas chromatography processing, and may include one or more processors executing instructions stored on a memory, and executing communications via communications circuitry based on guidance from processor(s) for conducting gas chromatography operations.

In operation, control equipment controls operations of analysis equipment. For example, control equipment provides governing control commands for operation of analysis modules of analysis equipment. Control equipment also provides control of electronic components within display assembly 112. For example, control equipment may control a display 120 (shown in FIG. 2B) of display assembly 112.

FIG. 2A is a section view taken along line 2A-2A in FIG. 1 and illustrates an example display assembly 112, and FIG. 2B is an exploded view of display assembly 112. Display assembly 112 may be in communication with analysis equipment in analysis compartment 108, with control equipment in control compartment 114, and/or with other electronic equipment. In some embodiments, display compartment 110 may additionally or alternatively be in communication with other electronic equipment internal or external to explosion-resistant device 100.

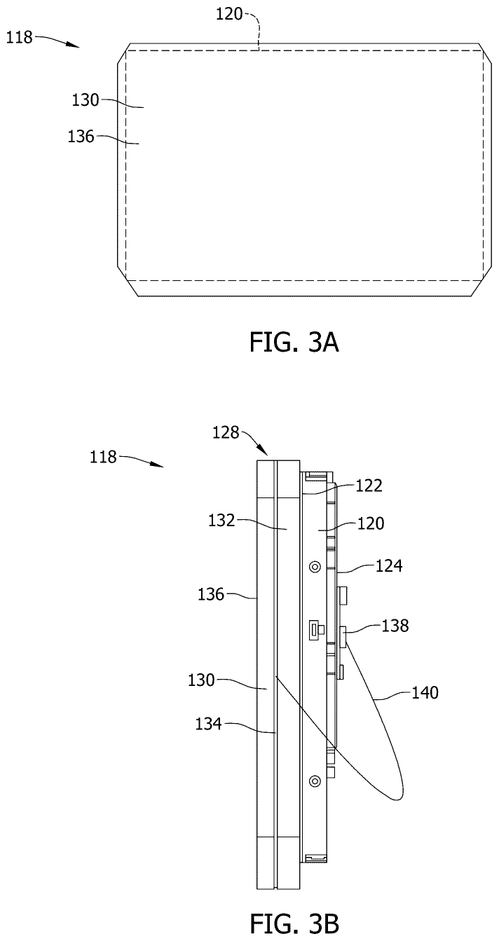

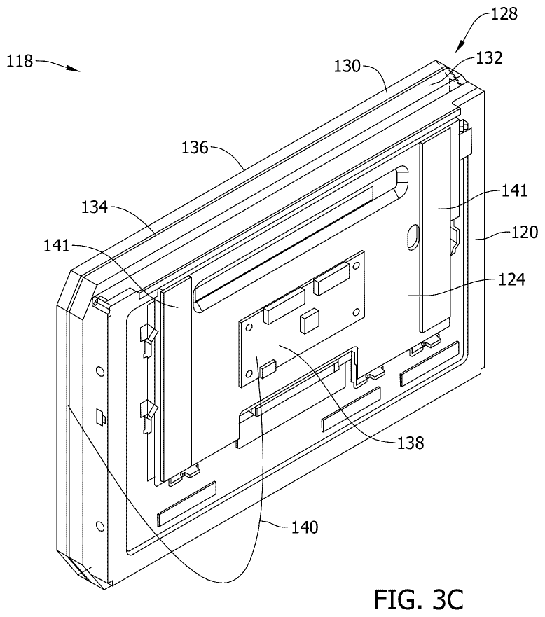

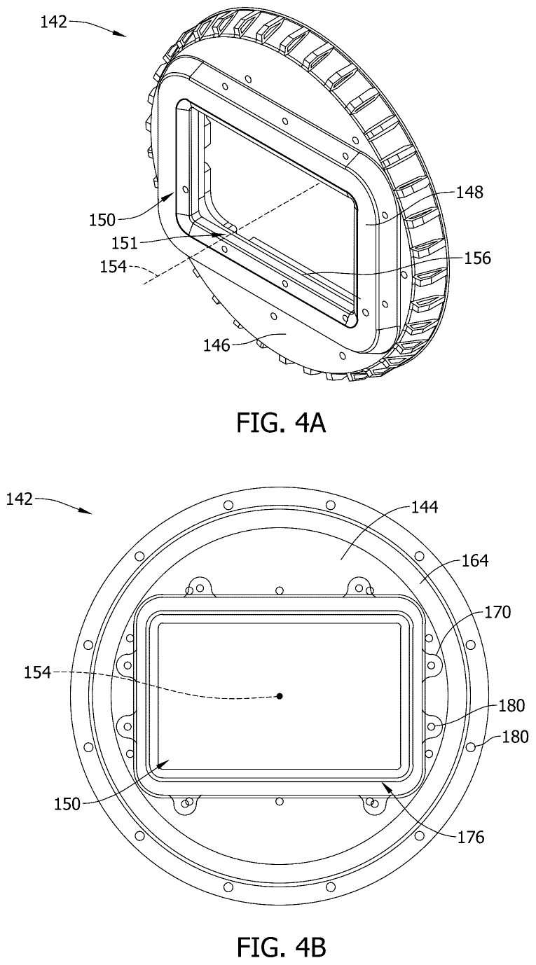

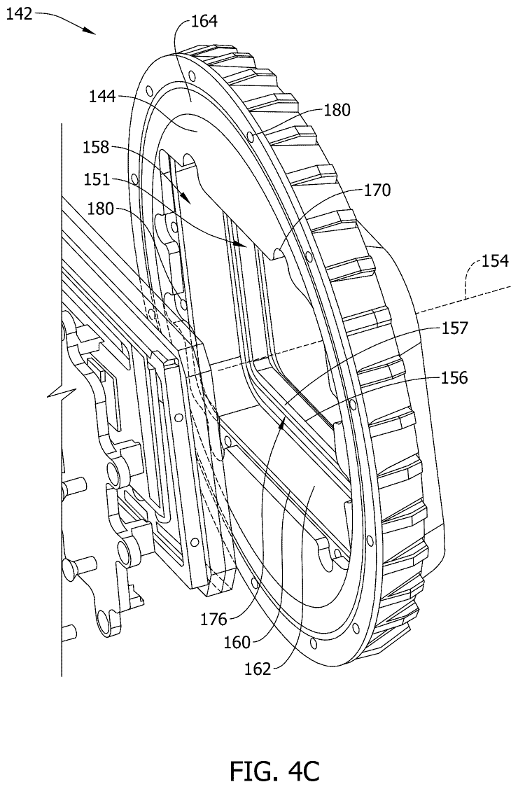

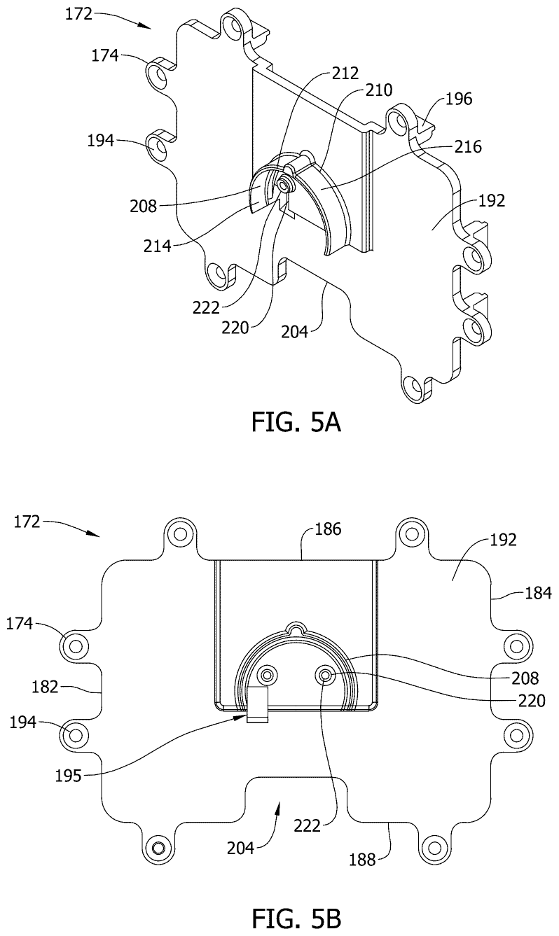

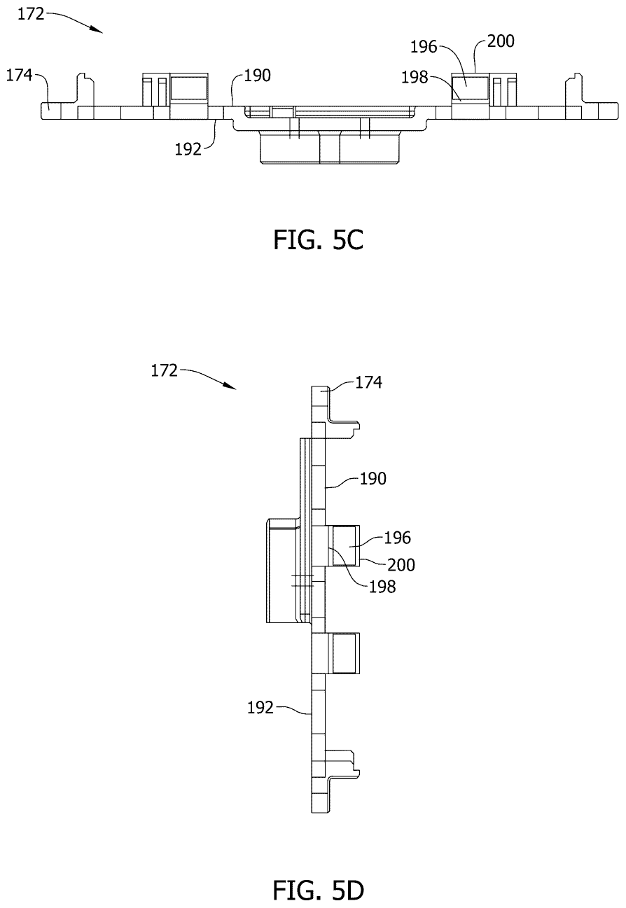

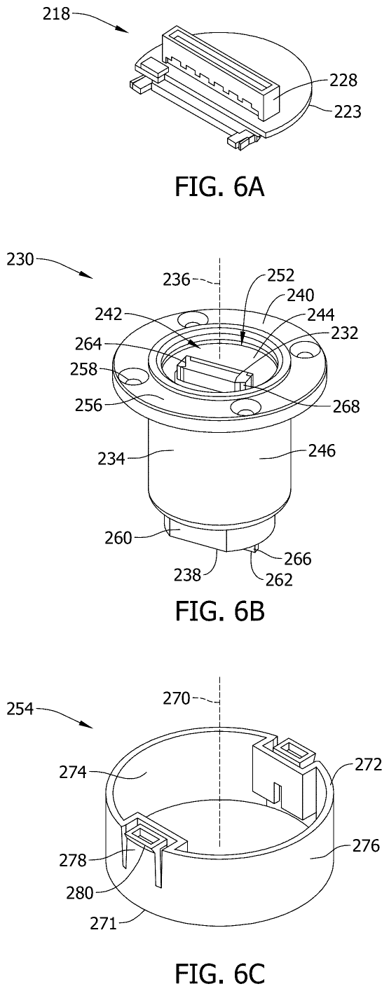

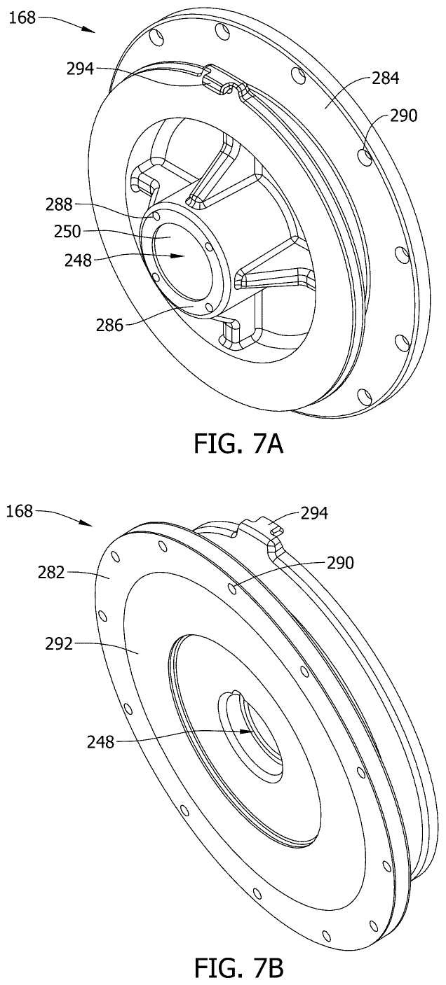

In the example embodiment, display assembly 112 includes a graphical interface assembly 118 (shown in FIGS. 3A-3C described later) positioned between a bezel plate 142 (shown in FIGS. 4A-4C described later) and a feed-through plate 168 (shown in FIGS. 7A and 7B described later), with a captivation plate 172 (shown in FIGS. 5A-5D described later) securing graphical interface assembly 118 within display compartment 110. Graphical interface assembly 118 is configured to receive input from a user and to display various information based on the input from the user. Graphical interface assembly 118 is configured to communicate with other electronic equipment via a display pass-through assembly 230 (shown in FIGS. 6B and 6C described later) positioned within feed-through plate 168.

In operation, display assembly 112 may receive input from a user and may communicate with other electronic components of explosion-resistant device 100 (e.g., analysis equipment and/or control equipment) and/or electronic components external to explosion-resistant device 100 to display various information.

FIGS. 3A-3C illustrate an example embodiment of graphical interface assembly 118. Graphical interface assembly 118 is received in display compartment 110. Graphical interface assembly 118 is configured to present visual information and receive input from a user.

In the example embodiment, graphical interface assembly 118 includes a display 120. Display 120 includes a front, displaying surface 122. Display 120 also includes a back surface 124. Display 120 may be rectangular in shape or may be of any suitable configuration that enables explosion-resistant device 100 to function as described herein.

In the example embodiment, graphical interface assembly 118 also includes a display sensor assembly 128. Display sensor assembly 128 includes a face plate 130. Display sensor assembly 128 also includes a backing plate 132. Backing plate 132 may be positioned between display 120 and face plate 130. Display sensor assembly 128 further includes a sensor layer 134. Sensor layer 134 may be positioned between face plate 130 and backing plate 132, and is configured to detect touch of a user.

In the example embodiment, face plate 130, backing plate 132, and display 120 each include similar outer profiles to one another and may each be rectangular. In other embodiments, face plate 130, backing plate 132, and display 120 may each independently have any suitable configuration that enables explosion-resistant device 100 to function as described herein.

In the example embodiment, graphical interface assembly 118 is a touch-screen interface that enables a user to input commands via touch sensors (e.g., sensor layer 134). In the example embodiment, sensor layer 134 includes projective capacitive (PCAP) touch sensors.

In the example embodiment, face plate 130 includes a front, touch surface 136. As described further later, a thickness of face plate 130 is less than a thickness of backing plate 132, and sensor layer 134 is positioned between face plate 130 and backing plate 132, which enhances the sensitivity of the touch-screen capability of graphical interface assembly 118 on front, touch surface 136 of face plate 130, while still providing explosion resistance. In other embodiments, the thickness of face plate 130 is greater than the thickness of backing plate 132, and sensor layer 134 is positioned between face plate 130 and backing plate 132, which enhances the sensitivity of the touch-screen capability of graphical interface assembly 118 on front, touch surface 136 of face plate 130, while still providing explosion resistance. Face plate 130 with an increased thickness while reducing the thickness of back plate 132 provides an enhanced explosion resistance without changing the combined thickness of face plate 130 and backing plate 132.

In some embodiments, display 120 may be positioned adjacent to sensor layer 134 without backing plate 132 in order to provide a clearer display to the user by eliminating a thickness of material between the user and display 120. Face plate 130 may still include suitable thicknesses that enable explosion-resistant device 100 to function as described herein.

In the example embodiment, face plate 130 and backing plate 132 are constructed from an explosion-resistant material. Face plate 130 and backing plate 132 are operable to help contain possible explosions within explosion-resistant device 100 and therefore enhance explosion resistance of explosion-resistant device 100. Face plate 130 and backing plate 132 are also operable to protect explosion-resistant device 100 from explosions and/or hazards originating external to explosion-resistant device 100. Face plate 130 and backing plate 132 are constructed from glass (e.g., flame-proof glass and/or explosion-proof glass) or thermoplastic (e.g., polycarbonate). Face plate 130 and backing plate 132 may be constructed from any suitable material that enables explosion-resistant device 100 to function as described herein.

In the example embodiment, sensor layer 134 is positioned between face plate 130 and backing plate 132 and is configured to detect touch of a user on or near front, touch surface 136 of face plate 130. Sensor layer 134 enables touch-screen input capability of graphical interface assembly 118. The sensitivity of sensor layer 134 is at least partially dependent on the thickness of face plate 130 that is positioned between sensor layer 134 and a user. As a thickness of a plate that is positioned between sensor layer 134 and a user (e.g., face plate 130) increases, the sensitivity of sensor layer 134 decreases, and thus it is more difficult for a user to input commands using graphical interface assembly 118 when face plate 130 is thick. In conventional explosion-resistant devices, the plate positioned between a sensor layer and a user is generally thick to enhance explosion resistance. The sensitivity of the touch-screen interface, however, is limited by the thickness of the single, thick plate positioned between the sensor layer and the user.

In the example embodiment, sensor layer 134 is positioned between face plate 130 and backing plate 132, and a user inputs a touch operation on front, touch surface 136 of face plate 130. In this way, the sensitivity of sensor layer 134 is dependent on the thickness of face plate 130 and is not dependent on the thickness of backing plate 132. Sensor layer 134 being positioned between face plate 130 and backing plate 132 enables enhanced sensitivity of sensor layer 134, which, in turn, enables enhanced accuracy and precision of user commands input to graphical interface assembly 118. Because the sensitivity of sensor layer 134 is not dependent on the thickness of backing plate 132, backing plate 132 may be of any suitable thickness such that the combined thickness of face plate 130 and backing plate 132 is suitable to enable explosion resistance of explosion-resistant device 100.

In the example embodiment, the combined thickness of face plate 130 and backing plate 132 may be 12 mm. In some embodiments, face plate 130 may have a thickness of 4 mm and backing plate 132 may have a thickness of 8 mm. In other embodiments, face plate 130 and backing plate 132 may each have a thickness of 6 mm. The combined thickness of 12 mm of face plate 130 backing plate 132 enables explosion-resistance of explosion-resistant device 100 while also reducing space within explosion-resistant device 100. The thickness of 4 mm or 6 mm of face plate 130 also enables enhanced sensitivity of sensor layer 134, such that the accuracy and precision of touch-screen operations input to graphical interface assembly 118 by a user are increased. The thickness of 8 mm or 6 mm of backing plate 132 does not affect the sensitivity of sensor layer 134 and is a thickness sufficient to enable explosion-resistance of the explosion-resistant device 100 when combined with the thickness of face plate 130. In other embodiments, face plate 130 and backing plate 132 may have any suitable thicknesses that enable explosion-resistant device 100 to function as described herein.

In the example embodiment, graphical interface assembly 118 further includes a sensor PCBA 138. Sensor PCBA 138 is coupled to display 120. Sensor PCBA 138 includes a processor coupled to at least one memory device. In the illustrated embodiment, sensor PCBA 138 is coupled to back surface 124 of display 120, but may be positioned in any suitable location that enables explosion-resistant device 100 to function as described herein. Sensor layer 134 may be connected to sensor PCBA 138 via wires or cables 140.

In the example embodiment, graphical interface assembly 118 further includes at least one damping component 141 coupled to back surface 124 of display 120. At least one damping component 141 is operable to prevent damage to graphical interface assembly 118 in case of unexpected impact to graphical interface assembly 118 (e.g., during assembly). At least one damping component 141 also protects sensor PCBA 138 from being damaged by other components when explosion-resistant device 100 is assembled.

In operation, when a user touches front, touch surface 136 of face plate 130, sensor layer 134 generates a signal corresponding to the location(s) where the user touches front, touch surface 136 of face plate 130. Sensor layer 134 transmits the signal to sensor PCBA 138, and sensor PCBA 138 processes the received signal and executes commands based on the signal by communicating with other electronic equipment of explosion-resistant device 100 (e.g., analysis equipment and/or control equipment) and/or other electronic equipment external to explosion-resistant device 100. For example, a user may indicate that they would like to view a specific set of data measured from a sample via touching a specific location (or making a series of touch operations) on front, touch surface 136 of face plate 130. Sensor layer 134 generates a signal corresponding to the touch operation(s) by the user, and transmits the signal to sensor PCBA 138. Sensor PCBA 138 processes the signal, communicates with other electronic equipment to obtain the requested data, and executes an operation to display the specific set of data on display 120.

In the example embodiment, display assembly 112 further includes bezel plate 142 adjacent to graphical interface assembly 118. FIGS. 4A-4C illustrate an example embodiment of bezel plate 142.

In the example embodiment, bezel plate 142 includes an interior surface 144 and an exterior surface 146. Bezel plate further includes a projection 148 projecting from exterior surface 146. Projection 148 forms a ring on exterior surface 146.

In the example embodiment, bezel plate 142 defines an opening 150. Opening 150 includes a front opening 151. Front opening 151 is defined by projection 148 and extends along a central axis 154 of bezel plate 142 from exterior surface 146 to a first edge 156 on interior surface 144.

In the example embodiment, opening 150 also includes a back opening 158 (shown in FIG. 4C) extending along central axis 154 from first edge 156 of interior surface 144 to a second edge 160 of interior surface 144 and defined by interior sides 162 of interior surface 144. Interior sides 162 define a perimeter of back opening 158 which is complementary to the perimeter of graphical interface assembly 118. Further, front opening 151 is smaller than back opening 158 such that the perimeter of front opening 151 is less than a perimeter of back opening 158.

In the example embodiment, interior surface 144 of bezel plate 142 includes a stepped surface 164. In the illustrated embodiment, stepped surface 164 extends radially about central axis 154 of bezel plate 142 (FIG. 4B). Stepped surface 164 defines a first portion of a flame path 166 (shown in FIG. 2B) between bezel plate 142 and a feed-through plate 168 when bezel plate 142 is coupled to feed-through plate 168.

In the example embodiment, bezel plate 142 further includes a plurality of notches 170. Notches 170 are defined in interior surface 144 of bezel plate 142. In the illustrated embodiment, notches 170 are sized and shaped to engage one or more tabs 174 of captivation plate 172 (shown in FIGS. 5A-5D described later) when captivation plate 172 is coupled to bezel plate 142.

In the example embodiment, bezel plate 142 also defines a groove 176 within a rim 157. Rim 157 defines an interior surface of projection 148, and rim 157 is part of interior surface 144 of bezel plate 142. In other embodiments, groove 176 may be formed in any suitable location that enables explosion-resistant device 100 to function as described herein.

In the example embodiment, a sealing component 178 (e.g., an O-ring—shown in FIG. 2B) is positioned within groove 176. Sealing component 178 is operable to seal the engagement of graphical interface assembly 118 with bezel plate 142 within display compartment 110 via fastening captivation plate 172 to bezel plate 142. In the example embodiment, sealing component 178 is constructed from rubber. In other embodiments, sealing component 178 may be constructed from any suitable material that enables explosion-resistant device 100 to function as described herein.

In operation, graphical interface assembly 118 is positioned within back opening 158 of bezel plate 142, and is secured within back opening 158 of bezel plate 142 via coupling captivation plate 172 to bezel plate 142, with graphical interface assembly 118 positioned between captivation plate 172 and bezel plate 142 such that face plate 130 sealingly engages sealing component 178.

In the example embodiment, bezel plate 142 further includes a plurality of recesses 180 that are sized and shaped to receive fasteners therein (FIG. 4B). In operation, graphical interface assembly 118, feed-through plate 168, and captivation plate 172 are coupled to bezel plate 142 via fasteners inserted into a subset of recesses 180. More specifically, in operation, graphical interface assembly 118 is positioned within back opening 158 of bezel plate 142 such that graphical interface assembly 118 sealingly engages sealing component 178. Then, captivation plate 172 may be coupled to bezel plate 142 via fasteners inserted into a subset of recesses 180. Finally, feed-through plate 168 may be fastened to bezel plate 142 via fasteners inserted into a subset of recesses 180.

FIG. 5A-5D illustrate an example of captivation plate 172. In the example embodiment, display assembly 112 further includes captivation plate 172. In the example embodiment, captivation plate 172 is fastened to bezel plate 142, with graphical interface assembly 118 positioned therebetween. In the example embodiment, captivation plate 172 extends from a first end 182 to a second end 184 and from a first side 186 to a second side 188. Captivation plate 172 also includes a front surface 190 and a back surface 192.

In the example embodiment, captivation plate 172 further includes tabs 174. Tabs 174 each include a through hole 194 and are sized to be received within a corresponding notch 170 of bezel plate 142. In operation, captivation plate 172 is fastened to bezel plate 142 via fasteners inserted into through holes 194 of captivation plate 172 and into a subset of recesses 180 of bezel plate 142.

Further, in operation, before fastening captivation plate 172 to bezel plate 142, graphical interface assembly 118 is positioned between captivation plate 172 and bezel plate 142. In the example embodiment, captivation plate 172 includes eight tabs 174 each including one through hole 194. In other embodiments, captivation plate 172 may include any suitable number of tabs 174 having any suitable configuration and any suitable number of through holes 194 that enable explosion-resistant device 100 to function as described herein.

In the example embodiment, captivation plate 172 further includes a plurality of prongs 196. Prongs 196 each extend from front surface 190 of captivation plate 172 at a first end 198 to a second end 200, and are operable to restrict movement of graphical interface assembly 118 relative to captivation plate 172. In the example embodiment, captivation plate 172 includes eight prongs 196. In other embodiments, captivation plate 172 may include any suitable number of prongs 196 having any suitable configuration that enables explosion-resistant device 100 to function as described herein.

In operation, when captivation plate 172 is fastened to bezel plate 142 with graphical interface assembly 118 positioned between captivation plate 172 and bezel plate 142, prongs 196 engage graphical interface assembly 118 and prevent movement of graphical interface assembly 118 relative to captivation plate 172. Prongs 196 also prevent movement of graphical interface assembly 118 relative to bezel plate 142 after captivation plate 172 is fastened to bezel plate 142.

Further, in operation, with captivation plate 172 fastened to bezel plate 142 with graphical interface assembly 118 positioned therebetween, a perimeter channel 202 (shown in FIG. 2A) is formed between graphical interface assembly 118 and interior sides 162 of interior surface 144 bezel plate 142. In the example embodiment, perimeter channel 202 between graphical interface assembly 118 and bezel plate 142 may be filled with encapsulant (e.g., is potted) in order to reduce space within explosion-resistant device 100 and to seal the display assembly 112 from the exterior environment. In the example embodiment, encapsulant includes cement. In other embodiments, encapsulant may include any suitable material the enables explosion-resistant device 100 to function as described herein.

In the example embodiment, captivation plate 172 further includes a cutout 204. Cutout 204 of captivation plate 172 is formed in second side 188 of captivation plate 172. In the example embodiment, captivation plate 172 includes one cutout 204 that may be rectangular. In other embodiments, captivation plate 172 may include any suitable number of cutouts 204 having any suitable configuration that enables explosion-resistant device 100 to function as described herein. In operation, cutout 204 enables access to a portion of graphical interface assembly 118 when captivation plate 172 is fastened to bezel plate 142, with graphical interface assembly 118 positioned therebetween.

In the example embodiment, captivation plate 172 further defines an opening 195. Opening 195 of captivation plate 172 is defined in a medial portion of captivation plate 172 and extends from front surface 190 to back surface 192 of captivation plate 172. In the example embodiment, captivation plate 172 includes one opening 195 that may be rectangular. In other embodiments, captivation plate 172 may include any suitable number of openings 195 having any suitable configuration and position that enables explosion-resistant device 100 to function as described herein. In operation, opening 195 enables electronic connection components (e.g., wires, cables, PCBAs) to pass through captivation plate 172.

In the example embodiment, captivation plate further includes a projection 208. Projection 208 extends from back surface 192 of captivation plate 172 at a first end 210 to a second end 212. Projection 208 includes an inner surface 214 and an outer surface 216. In some embodiments, projection 208 may be semi-circular and may be located near the center of captivation plate 172.

In the example embodiment, projection 208 defines a perimeter. Specifically, projection 208 defines a perimeter of outer surface 216 and a perimeter of inner surface 214. A display interface PCBA 218 (shown in FIG. 6A) includes a perimeter complementary to the perimeter of projection 208 (specifically, to the perimeter of inner surface 214 of projection 208). In operation, display interface PCBA 218 is coupled to captivation plate 172 such that projection 208 at least partially surrounds display interface PCBA 218. More specifically, display interface PCBA 218 is coupled to captivation plate 172 such that inner surface 214 of projection is adjacent to display interface PCBA 218.

In the example embodiment, captivation plate 172 further includes a pair of protrusions 220 mounted to captivation plate 172. Protrusions 220 each include a recess 222 that is operable to receive a fastener therein. Protrusions 220 may be positioned near projection 208. In other embodiments, protrusions may have any suitable position that enables explosion-resistant device 100 to function as described herein.

In operation, projection 208 of captivation plate 172 enables easier installation of display interface PCBA 218 thereon by providing a polarized or keyed coupling between display interface PCBA 218 and captivation plate 172. Polarized or keyed couplings include, for example, two components that may only be coupled in a discrete number of configurations. In the example embodiment, the coupling between display interface PCBA 218 and captivation plate 172 is a polarized or keyed coupling because display interface PCBA 218 may be installed on captivation plate 172 by aligning the perimeter of display interface PCBA 218 with the complementary perimeter of inner surface 214 of projection 208 of captivation plate 172 such that through holes 226 in display interface PCBA 218 are aligned with recesses 222 in captivation plate 172. In the example embodiment, if the perimeter of display interface PCBA 218 is not aligned with the perimeter of inner surface 214 of projection 208 of captivation plate 172, then through holes 226 of display interface PCBA 218 will not be aligned with recesses 222 of captivation plate 172, thereby preventing coupling of display interface PBCA 218 with captivation plate 172.

Further, in operation, graphical interface assembly 118 is positioned within back opening 158 of bezel plate 142, and captivation plate 172 is coupled to bezel plate 142. At least one damping component 141 of graphical interface assembly 118 provides a cushion between captivation plate 172 and back surface 124 of display 120 in order to protect sensor PCBA 138 from being damaged. Captivation plate 172 presses graphical interface assembly 118 into back opening 158 of bezel plate 142 such that space within display compartment 110 is reduced. Captivation plate 172 enables a compact arrangement of components within display compartment 110.

In the example embodiment, display assembly 112 further includes display interface PCBA 218. FIG. 6A illustrates an example display interface PCBA 218. In the example embodiment, display interface PCBA 218 includes an outer surface 223 that has a perimeter that is complementary to the perimeter of inner surface 214 of projection 208 of captivation plate 172. Display interface PCBA 218 also includes a processor coupled to at least one memory device. Display interface PCBA 218 further includes through holes 226 (shown in FIG. 2B) that are operable to receive fasteners therein. Display interface PCBA 218 also includes an electronic connector 228 that is operable to electrically and mechanically connect display interface PCBA 218 to other electronic components. In the illustrated embodiment, display interface PCBA 218 may be semi-circular. In other embodiments, display interface PCBA 218 may have any suitable configuration the enables explosion-resistant device 100 to function as described herein.

In operation, display interface PCBA 218 is fastened to captivation plate 172 via aligning the perimeter of outer surface 223 of display interface PCBA 218 with the perimeter of inner surface 214 of projection 208 of captivation plate 172 and inserting fasteners into through holes 226 of display interface PCBA 218 and into recesses 222 of protrusions 220 of captivation plate 172. Display interface PCBA 218 is fastened to captivation plate 172 such that display interface PCBA 218 may be at least partially surrounded by projection 208 of captivation plate 172. In the example embodiment, projection 208 of captivation plate 172, along with the perimeter of outer surface 223 of display interface PCBA 218, provide a polarized or keyed coupling for coupling display interface PCBA 218 to captivation plate.

Further, in operation, display interface PCBA 218 is electrically coupled to sensor PCBA 138 via electronic connection components (e.g., via wires, cables, PCBAs) passing through opening 195 in captivation plate 172 such that display interface PCBA 218 and sensor PCBA 138 may communicate with each other. Display interface PCBA 218 is also electrically coupled to a display pass-through assembly 230 (shown in FIGS. 6B and 6C).

In the example embodiment, display assembly 112 further includes display pass-through assembly 230. FIG. 6B illustrates an example display pass-through assembly 230. In the example embodiment, display pass-through assembly 230 includes a housing 234. Housing 234 extends radially about a central axis 236 and extends longitudinally from a first end 238 to a second end 240. Housing 234 also defines a passage 242 therein. Housing 234 also includes an interior surface 244 defining passage 242 and an exterior surface 246. Exterior surface 246 of housing 234 may be formed complementary to an interior surface 250 of a passage 248 of feed-through plate 168 (shown in FIGS. 7A and 7B). Interior surface 244 of housing 234 defines a groove 252 near second end 240 of housing 234 that is operable to secure a retainer 254 (shown in FIG. 6C) within housing 234.

In the example embodiment, housing 234 further includes a radial flange 256 located near second end 240 of housing 234. Radial flange 256 includes a plurality of through holes 258 that are each operable to receive a fastener therein. In the example embodiment, housing 234 includes four through holes 258 in radial flange 256. In other embodiments, housing 234 may include any suitable number of through holes 258 in radial flange 256 that enable explosion-resistant device 100 to function as described herein.

In the example embodiment, housing 234 also includes a connection portion 260 located adjacent first end 238 of housing 234. Connection portion 260 includes a perimeter, and at least part of the perimeter of connection portion 260 may be complementary to the perimeter of inner surface 214 of projection 208 of captivation plate 172. In operation, connection portion 260 enables easier alignment and connection between electronic components of display pass-through assembly 230 (e.g., control-display communication PCBA 232) and display interface PCBA 218.

In the example embodiment, display pass-through assembly 230 also includes control-display communication PCBA 232. Control-display communication PCBA 232 is positioned within housing 234. Control-display communication PCBA 232 extends from a first end 262 to a second end 264. Control-display communication PCBA 232 also includes a processor coupled to at least one memory device.

In the example embodiment, control-display communication PCBA 232 further includes an electronic connector 266 at first end 262 thereof. In operation, electronic connector 266 at first end 262 of control-display communication PCBA 232 is operable to mechanically and electrically couple to electronic connector 228 of display interface PCBA 218, thereby connecting control-display communication PCBA 232 to display interface PCBA 218. In other embodiments, control-display communication PCBA 232 may have any suitable configuration and may include any suitable components that enables explosion-resistant device 100 to function as described herein.

In the example embodiment, control-display communication PCBA 232 also includes an electronic connector 268 at second end 264 thereof. In operation, control-display communication PCBA 232 is electrically coupled to analysis equipment, control equipment, and/or other electronic components via electronic connector 268 at second end 264 of control-display communication PCBA 232. Analysis equipment, control equipment, and/or other electronic components are connected to and communicate with display interface PCBA 218, and thus with display assembly 112, via control-display communication PCBA 232, rather than by wires and/or cables. For example, communication between the control compartment 114 and the display compartment 110 does not include cabling. As used herein, cabling refers to connections and communications between electrical and/or electronic components via wires and/or cables that may move and/or develop twist relative to the electrical and/or electronic components.

In the example embodiment, display pass-through assembly 230 further includes retainer 254 positioned within housing 234. FIG. 6C illustrates an example retainer 254. In the example embodiment, retainer 254 extends radially about a central axis 270. Retainer 254 also extends longitudinally (e.g., along central axis 270) from a first end 271 to a second end 272 and includes an interior surface 274 and an exterior surface 276. Retainer 254 may be cylindrical in shape or may be of any suitable configuration that enables explosion-resistant device 100 to function as described herein.

In the example embodiment, retainer 254 also includes tabs 278 that are operable to secure retainer 254 and control-display communication PCBA 232 within housing 234 of display pass-through assembly 230. Tabs 278 may be bent out of the undeformed position shown in FIG. 6C (e.g., towards or away from central axis 270) and into a deformed position. When released from the deformed position, tabs 278 return to the undeformed position. In the example embodiment, tabs 278 also each include an outer, engagement edge 280 for engaging groove 252. In other embodiments, tabs 278 may be of any suitable configuration that enables explosion-resistant device 100 to function as described herein.

In operation, with control-display communication PCBA 232 inserted into housing 234, retainer 254 is positioned within housing 234 such that outer, engagement edge 280 of each tab 278 is aligned with groove 252 defined in housing 234. Once outer, engagement edge 280 of each tab 278 is aligned with groove 252, tabs 278 are released from the deformed position and return to the undeformed position, thereby engaging the groove 252 defined in housing 234 with outer, engagement edge 280 and securing retainer 254 within housing 234.

In the example embodiment, display pass-through assembly 230 may be encapsulated. Components of display pass-through assembly 230 (e.g., control-display communication PCBA 232 and retainer 254) are contained within housing 234, and the remaining space within housing 234 of display pass-through assembly 230 may be at least partially filled with encapsulant (e.g., potted) in order to reduce space within explosion-resistant device 100. In some embodiments, space near electronic connectors 266, 268 of control-display communication PCBA 232 is not filled with encapsulant in order to leave room for connecting control-display communication PCBA 232 to other electronic components via electronic connectors 266, 268. In the example embodiment, encapsulant includes cement. In other embodiments, encapsulant may include any suitable material the enables explosion-resistant device 100 to function as described herein.

In the example embodiment, display assembly 112 further includes feed-through plate 168. FIGS. 7A and 7B illustrate an example feed-through plate 168. In the example embodiment, feed-through plate 168 includes a front surface 282 and a back surface 284. Feed-through plate 168 may have a circular outer profile or may be of any suitable configuration that enables explosion-resistant device 100 to function as described herein.

In the example embodiment, feed-through plate 168 further includes passage 248. Passage 248 extends from front surface 282 to back surface 284 and is defined by interior surface 250. Passage 248 is sized and shaped to receive housing 234 of display pass-through assembly 230, and therefore control-display communication PCBA 232, therein. Specifically, exterior surface 246 of housing 234 of display pass-through assembly 230 may be formed nearly complementary to interior surface 250 that defines passage 248. However, exterior surface 246 of housing 234 may be formed such that display pass-through assembly 230 and feed-through plate define a flame path 285 (shown in FIG. 2B) when display pass-through assembly 230 is inserted into passage 248 of feed-through plate 168. Specifically, flame path 285 is defined between exterior surface 246 of housing 234 and interior surface 250 of feed-through plate 168 when housing 234 is inserted into passage 248.

In the example embodiment, feed-through plate 168 further incudes an engagement surface 286 positioned proximate to passage 248 on back surface 284. Engagement surface 286 may be circular or may have any suitable configuration the enables explosion-resistant device 100 to function as described herein. Engagement surface 286 includes a plurality of recesses 288 sized and shaped to receive fasteners therein. In the example embodiment, feed-through plate 168 includes four recesses 288 in engagement surface 286. In other embodiments, engagement surface 286 of feed-through plate 168 may include any suitable number of recesses 288 that enables explosion-resistant device 100 to function as described herein.

In the example embodiment, feed-through plate 168 further includes a plurality of through holes 290 sized and shaped to receive fasteners therein. In operation, through holes 290 of feed-through plate 168 are operable to fasten feed-through plate 168 to bezel plate 142 via fasteners inserted into through holes 290 of feed-through plate 168 and into corresponding recesses 180 in bezel plate 142. In the example embodiment, feed-through plate 168 includes twelve through holes 290. In other embodiments, feed-through plate 168 may include any suitable number of through holes 290 that enables explosion-resistant device 100 to function as described herein.

In the example embodiment, feed-through plate 168 also includes a stepped surface 292 on front surface 282. Stepped surface 292 defines a second portion of flame path 166 between bezel plate 142 and feed-through plate 168. In operation, when feed-through plate 168 is fastened to bezel plate 142, bezel plate 142 and feed-through plate 168 define flame path 166. Specifically, stepped surface 164 of bezel plate 142 and stepped surface 292 of feed-through plate 168 define flame path 166.

In the example embodiment, feed-through plate 168 further includes an alignment tab 294. Alignment tab 294 is operable to align feed-through plate 168 with other components of explosion-resistant device 100 before fastening feed-through plate 168 to other components of explosion-resistant device 100. For example, in operation, alignment tab 294 may be used to align feed-through plate 168 or display assembly 112 with analysis equipment and/or control equipment before fastening feed-through plate 168 to analysis equipment and/or control equipment. In other embodiments, alignment tab 294 may be used to align feed-through plate 168 with any suitable components that enable explosion-resistant device 100 to function as described herein.

In operation, graphical interface assembly 118 is placed on captivation plate 172, such that prongs 196 of captivation plate 172 surround graphical interface assembly 118 on four sides. Then, graphical interface assembly 118 is placed within back opening 158 of bezel plate 142, such that graphical interface assembly 118 sealingly engages sealing component 178, and captivation plate 172 is fastened to bezel plate 142. Specifically, tabs 174 of captivation plate 172 are aligned with corresponding notches 170 of bezel plate 142, and fasteners are inserted into through holes 194 of captivation plate 172 and into corresponding recesses 180 of bezel plate 142. Display interface PCBA 218 is then fastened to captivation plate 172 via fasteners inserted into through holes 226 of display interface PCBA 218 and into recesses 222 of captivation plate 172.

Next, feed-through plate 168 is fastened to bezel plate 142 via fasteners inserted into through holes 290 of feed-through plate 168 and into corresponding recesses 180 of bezel plate 142. Feed-through plate 168 and bezel plate 142 define display compartment 110 between feed-through plate 168 and bezel plate 142.

Next, display pass-through assembly 230 is inserted into passage 248. Specifically, with control-display communication PCBA 232 inserted into housing 234, first end 238 of housing 234 is inserted into passage 248 at back surface 284 of feed-through plate 168 until (i) electronic connector 266 at first end 262 of control-display communication PCBA 232 engages electronic connector 228 of display interface PCBA 218 and/or (ii) radial flange 256 of housing 234 of display pass-through assembly 230 engages engagement surface 286 of feed-through plate 168. Then, through holes 258 in radial flange 256 and recesses 288 in feed-through plate 168 are aligned, and a fastener is inserted through each through hole 258 of radial flange 256 and into corresponding recess 288 in feed-through plate 168, thereby securing display pass-through assembly 230 to feed-through plate 168.

Finally, retainer 254 is inserted into passage 242 of housing 234 and is secured to housing 234, thereby securing control-display communication PCBA 232 within housing 234 at second end 240 of housing 234. Specifically, first end 271 of retainer 254 is inserted into second end 240 of housing 234 with tabs 278 bent toward central axis 270, thereby allowing unrestricted longitudinal movement of retainer 254 within passage 242. Retainer 254 is positioned within passage 242 such that outer, engagement edge 280 of each tab 278 is aligned with groove 252 defined in housing 234. Once outer, engagement edge 280 of each tab 278 is aligned with groove 252, tabs 278 are released from the deformed position and return to the undeformed position, thereby engaging the groove 252 defined in housing 234 with outer, engagement edge 280 of each tab 278 and securing retainer 254 within housing 234.

In the example embodiment, control-display communication PCBA 232 is longitudinally secured within housing 234 (e.g., along central axis 236) via retainer 254 at second end 240 of housing 234 and via display interface PCBA 218 at first end 238 of housing 234. In other embodiments, control-display communication PCBA 232 may be secured within housing 234 using any suitable components that enable explosion-resistant device 100 to function as described herein.

In the example embodiment, only space within display pass-through assembly 230 and space between bezel plate 142 and graphical interface assembly 118 are filled with encapsulant. Further encapsulant is not required in display compartment 110 due to the compact design of explosion-resistant device 100 and due to the inclusion of flame paths 166, 285 within the explosion-resistant device 100. In other embodiments, explosion-resistant device 100 may include encapsulant at any suitable location that enables explosion-resistant device 100 to function as described herein.

Referring back to FIG. 2C, another example display assembly 112-c is shown. FIG. 2C is a sectional view taken along line 2A-2A in FIG. 1 and illustrates another example display assembly 112-c including another example embodiment of a bezel plate 142-c. As shown in FIG. 2C, display assembly 112-c is similar to display assembly 112. Components of display assembly 112 include identical numbering to similar components of the display assembly 112-c, with different components (e.g., bezel plate 142-c) including different reference numbers.

In the example embodiment, bezel plate 142-c includes a plurality of threads 201, and an interior ring 203. Bezel plate 142-c also includes a retaining ring 205 that includes a plurality of threads 207. Retaining ring 205 may be removable. Threads 201 of bezel plate 142-c are complementary to threads 207 of retaining ring 205. Bezel plate 142-c may also include a groove and a sealing component (not shown) similar to groove 176 and sealing component 178 of bezel plate 142, respectively. Bezel plate 142-c may further define a first portion of a flame path between bezel plate 142-c and feed-through plate 168-c when bezel plate 142-c is coupled to feed-though plate 168-c, similar to stepped surface 164 of bezel plate 142 forming a first portion of flame path 166 formed between bezel plate 142 and feed-through plate 168.

In operation, to assemble display assembly 112-c, backing plate 132 is placed within interior ring 203, and face plate 130 is placed between interior ring 203 and retaining ring 205, with sensor layer 134 positioned between backing plate 132 and face plate 130. Then, retaining ring 205 is threaded on to bezel plate 142-c via threads 207 of retaining ring 205 engaging threads 201 of bezel plate 142-c. Retaining ring 205 engages front, touch surface 136 of face plate 130, thereby securing face plate 130 and backing plate 132 within bezel plate 142-c. Display 120 is then secured between bezel plate 142-c and captivation plate 172 by coupling captivation plate 172 to bezel plate 142-c with display 120 placed between backing plate 132 and captivation plate 172, and assembling the remaining components of display assembly 112-c as described above with respect to display assembly 112.

In the example embodiment, a channel 209 between face plate 130, interior ring 203, retaining ring 205, and interior surface 144 of bezel plate 142-c is filled with encapsulant, as is passage 248 of feed-through plate 168.

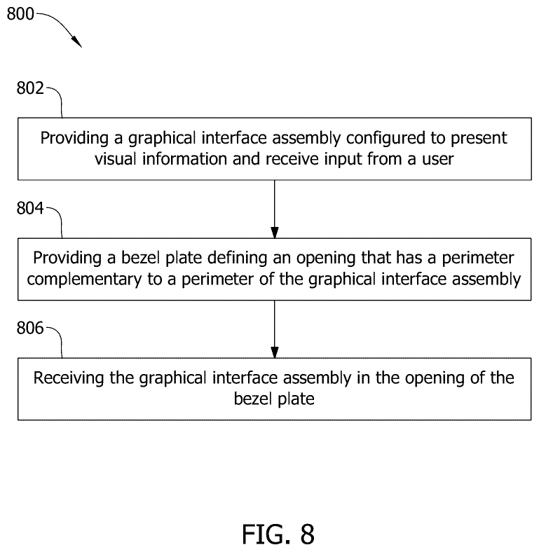

FIG. 8 is an exemplary method 800 of assembling a device for a harsh and hazardous environment. The device may be explosion-resistant device 100 described herein. Method 800 includes providing 802 a graphical interface assembly configured to present visual information and receive input from a user. The graphical interface assembly includes a face plate, a backing plate, and a sensor layer positioned between face plate and backing plate, and the sensor layer is configured to detect touch of the user. The graphical interface assembly may be graphical interface assembly 118 described herein including face plate 130, backing plate 132, and sensor layer 134 as also described herein. Method 800 further includes providing 804 a bezel plate defining an opening that has a perimeter complementary to a perimeter of the graphical interface assembly, and receiving 806 the graphical interface assembly in opening of the bezel plate. The bezel plate may be bezel plate 142 described herein. The device may be explosion resistant.

In some embodiments, method 800 further includes fastening a captivation plate with the bezel plate with the graphical interface assembly positioned between the captivation plate and the bezel plate. The captivation plate may be captivation plate 172 that is described herein.

In some embodiments, fastening the captivation plate further includes positioning an O-ring into a groove defined along the perimeter of the opening of the bezel plate, and compressing the O-ring against the graphical interface assembly by fastening the captivation plate with the bezel plate. The O-ring may be sealing component 178 that is described herein.

In some embodiments, method 800 further includes installing a display interface PCBA to the captivation plate by aligning a perimeter of the display interface PCBA with a perimeter of a projection extending from the captivation plate, and electrically coupling the display interface PCBA with a PCBA of the graphical interface assembly. The display interface PCBA may be display interface PCBA 218 described herein, the projection may be projection 208 described herein, and the PCBA of the graphical interface assembly may be sensor PCBA 138 described herein.

In some embodiments, method 800 further includes fastening a feed-through plate with the bezel plate with the graphical interface assembly positioned between the feed-through plate and the bezel plate. The feed-through plate may be feed-through plate 168 described herein.

In some embodiments, fastening the feed-through plate further includes receiving a display pass-through assembly in a passage defined by the feed-through plate, and fastening the display pass-through assembly with the feed-through plate. The display pass-through assembly may be display pass-through assembly 230 described herein.

At least one technical effect of the systems and methods described herein includes (a) enhanced touch-screen sensitivity of graphical interface assemblies in explosion-resistant devices; (b) an explosion-resistant device that reduces a required amount of encapsulant in order to meet a standard due to flame paths formed within the explosion-resistant device; (c) reducing space within the explosion-resistant device in which explosive and/or flammable gases may collect due to replacement of some wires and/or cables with PCBAs and due to compact design; (d) better electrical connection between electrical components due to replacement of some wires and/or cables with PCBAs; and (e) simplifying a process of assembling explosion-resistant devices due to keyed or polarized connections between components.

Exemplary embodiments of systems and methods of explosion management are described above in detail. The systems and methods are not limited to the specific embodiments described herein but, rather, components of the systems and/or operations of the methods may be utilized independently and separately from other components and/or operations described herein. Further, the described components and/or operations may also be defined in, or used in combination with, other systems, methods, and/or devices, and are not limited to practice with only the systems described herein.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. An explosion-resistant device, comprising:
an enclosure defining a control compartment and a display compartment, the display compartment being isolated from the control compartment; and
a graphical interface assembly received in the display compartment, the graphical interface assembly configured to present visual information and receive input from a user, wherein the graphical interface assembly comprises:
a display sensor assembly comprising:
a face plate;
a backing plate; and
a sensor layer positioned between the face plate and the backing plate and configured to detect touch of the user.

2. The explosion-resistant device of claim 1, wherein the face plate has a thickness less than a thickness of the backing plate.

3. The explosion-resistant device of claim 1, wherein the face plate has a thickness greater than a thickness of the backing plate.

4. The explosion-resistant device of claim 1, further comprising:
a bezel plate; and
a feed-through plate,
wherein the bezel plate and the feed-through plate define the display compartment.

5. The explosion-resistant device of claim 4, wherein the bezel plate defines an opening having a perimeter complementary to a perimeter of the graphical interface assembly.

6. The explosion-resistant device of claim 5, wherein the bezel plate and the graphical interface assembly define a perimeter channel between the bezel plate and the graphical interface assembly, and encapsulant is filled in the perimeter channel.

7. The explosion-resistant device of claim 4, further comprising a captivation plate fastened to the bezel plate, with the graphical interface assembly positioned between the captivation plate and the bezel plate.

8. The explosion-resistant device of claim 7, wherein the captivation plate further comprises a projection extending from the captivation plate, the projection defining a perimeter, the explosion-resistant device further comprises a display interface printed circuit board assembly (PCBA) having a perimeter complementary to the perimeter of the projection.

9. The explosion-resistant device of claim 4, wherein the bezel plate is fastened with the feed-through plate, and the bezel plate and the feed-through plate define a first flame path.

10. The explosion-resistant device of claim 4, further comprising a display pass-through assembly, wherein the feed-through plate defines a passage sized to receive the display pass-through assembly therethrough.

11. The explosion-resistant device of claim 10, further comprising a display interface printed circuit board assembly (PCBA), wherein the display pass-through assembly comprises a control-display communication PCBA electrically and mechanically coupled with the display interface PCBA.

12. The explosion-resistant device of claim 10, wherein the display pass-through assembly and the feed-through plate define a second flame path.

13. The explosion-resistant device of claim 1, wherein communication between the control compartment and the display compartment does not include cabling.

14. The explosion-resistant device of claim 1, wherein communication between the control compartment and the display compartment is via a printed circuit board assembly (PCBA).

15. A method of assembling a device for a harsh and hazardous environment, comprising:
providing a graphical interface assembly configured to present visual information and receive input from a user, wherein the graphical interface assembly includes:
a face plate;
a backing plate;
a sensor layer positioned between the face plate and the backing plate and configured to detect touch of the user;
providing a bezel plate defining an opening that has a perimeter complementary to a perimeter of the graphical interface assembly; and
receiving the graphical interface assembly in the opening of the bezel plate,
wherein the device is explosion resistant.

16. The method of claim 15, further comprising:
fastening a captivation plate with the bezel plate with the graphical interface assembly positioned between the captivation plate and the bezel plate.

17. The method of claim 16, wherein fastening the captivation plate further comprises:
positioning an O-ring into a groove defined along the perimeter of the opening of the bezel plate; and
compressing the O-ring against the graphical interface assembly by fastening the captivation plate with the bezel plate.

18. The method of claim 16, further comprising:
installing a display interface printed circuit board assembly (PCBA) to the captivation plate by:
aligning a perimeter of the display interface PCBA with a perimeter of a projection extending from the captivation plate; and
electrically coupling the display interface PCBA with a PCBA of the graphical interface assembly.

19. The method of claim 15, further comprising:
fastening a feed-through plate with the bezel plate with the graphical interface assembly positioned between the feed-through plate and the bezel plate.

20. The method of claim 19, wherein fastening the feed-through plate further comprises:
receiving a display pass-through assembly in a passage defined by the feed-through plate; and
fastening the display pass-through assembly with the feed-through plate.
